(19) United States
(12) Patent Application Publication
(10) Pub. No.: US 2021/0364550 A1
(43) Pub. Date: Nov. 25, 2021

(54) TESTING SYSTEM AND TESTING METHOD

(71) Applicant: TOKYO ELECTRON LIMITED, Tokyo (JP)

(72) Inventor: Tetsuya KAGAMI, Yamanashi (JP)

(21) Appl. No.: 16/649,928

(22) PCT Filed: Jul. 27, 2018
(86) PCT No.: PCT/JP2018/028245

§ 371 Date: Mar. 23, 2020

(30) Foreign Application Priority Data
Sep. 28, 2017 (JP) 2017-187559

(51) Int. Cl. G01R 1/073; G01R 31/28

(52) U.S. Cl. CPC G01R 1/07307; G01R 31/2893; G01R 31/2868

(57) ABSTRACT

This testing system comprises a prober, a tester, a prober control unit for controlling the prober, and a tester control unit for controlling the tester, wherein the tester control unit causes the tester to execute a test which is composed of a plurality of parts on a device to be tested formed on a test body in addition to acquiring an estimated test ending time when the test has reached a predetermined stage, and sends a control signal to the prober control unit so as to transfer the test body into a testing chamber housing the tester before the estimated test ending time.

### TECHNICAL FIELD

The present disclosure relates to a testing system and a testing method for testing an object to be tested.

### BACKGROUND

In a semiconductor device manufacturing process, electrical characteristics of a plurality of devices (IC chips) formed on a semiconductor wafer (hereinafter, simply referred to as “wafer”) are tested after all necessary processes are performed on the wafer. A testing system for testing such electrical characteristics generally includes a prober and a tester. The prober includes a wafer stage, an aligner for position-aligning the wafer, and a wafer transfer system and further includes a probe card having probes to be in contact with the devices formed on the wafer. The tester applies electrical signals to the devices through the probe card to test various electrical characteristics of the devices.

There is known a technique capable of efficiently testing electrical characteristics of multiple wafers by arranging multiple testing units in multiple stages, each testing unit including a wafer stage, a probe card, and a tester. On each stage, the multiple testing units are arranged horizontally, and a common aligner to perform position-alignment on the wafers is provided for the horizontally arranged testing units (see, e.g., Patent Document 1).

In the testing system, a FOUP serving as a container for accommodating a plurality of wafers is installed on each of a plurality of ports in a loading/unloading area.

Accordingly, a plurality of wafers can be consecutively tested.

The FOUP is installed based on an end signal outputted from a tester when the testing of wafers in the previous one or all FOUPs installed on the plurality of ports has been completed. In this case, depending on devices formed on the wafer, it is difficult to predict an estimated test ending time so that it is difficult to install the FOUP at an optimal timing. Therefore, if the collection of the FOUP and the installation of the next FOUP have not been completed at the time when the testing of the wafers of the previous FOUP has been completed, the standby time of the testing system increases and the operation rate decreases.

Therefore, Patent Document 2 suggests a technique for calculating an estimated processing ending time for a FOUP based on contents of recipes specified in advance for wafers in the FOUP before the processings on the wafers in the FOUP are completed, and then outputting the estimated processing ending time to a host.

### PRIOR ARTS

Patent Document 1: Japanese Patent Application Publication No. 2016-46285
Patent Document 2: Japanese Patent Application Publication No. 2016-192457

The present disclosure provides a testing system and a testing method capable of reducing a standby time of a tester in testing an individual object to be tested.

### SUMMARY

In accordance with an aspect of the present disclosure, there is provided a testing system including: a prober including a stage configured to hold a target object on which a plurality of devices to be tested is formed in a testing chamber, a loading/unloading port on which a container accommodating a plurality of target objects is mounted, a transfer unit configured to transfer each of the target objects from the container to the stage, and a probe card having a plurality of probes to be in contact with the devices to be tested formed on each of the target objects; at least one tester configured to apply electrical signals to the devices formed on each of the target objects through the probe card in the testing chamber and test electrical characteristics of the devices; a prober control unit configured to control the prober; and a tester control unit configured to control the tester. The tester control unit causes the tester to execute a test including a plurality of parts on the devices, acquires an estimated test ending time when the test has reached a predetermined stage, and transmits a control signal to the prober control unit so that a next target object is to be loaded into the testing chamber having the tester before the estimated test ending time.

### Effect of the Invention

In accordance with the aspect of the present disclosure, it is possible to reduce a standby time of the tester in testing an individual object to be tested.

### BRIEF DESCRIPTION OF THE DRAWINGS

FIG. 1 is a horizontal cross-sectional view schematically showing an overall configuration of a testing system according to an embodiment of the present disclosure.

FIG. 2 is a cross-sectional view taken along a line II-II′ of the testing system shown in FIG. 1.

FIG. 3 shows a schematic configuration of a testing unit in the testing system and explains a configuration from a test circuit board of a tester to a wafer.

FIG. 4 is a block diagram showing an example of a hardware configuration of a prober control unit.

FIG. 5 is a block diagram showing an example of a hardware configuration of a tester control unit.

FIG. 6 is a functional block diagram for explaining a main control of the prober control unit and the tester control unit according to the embodiment of the present disclosure.

FIG. 7 is a flowchart showing a schematic flow on a tester side in a testing method of the testing system according to the embodiment of the present disclosure.

FIG. 8 is a flowchart showing a control flow on a prober control unit 40 side in the case of receiving a control signal from a tester control unit 60.

### DETAILED DESCRIPTION

Hereinafter, embodiments of the present disclosure will be described in detail with reference to the accompanying drawings.

<Overall Configuration of the Testing System>

First, an overall configuration of a testing system according to an embodiment will be described.

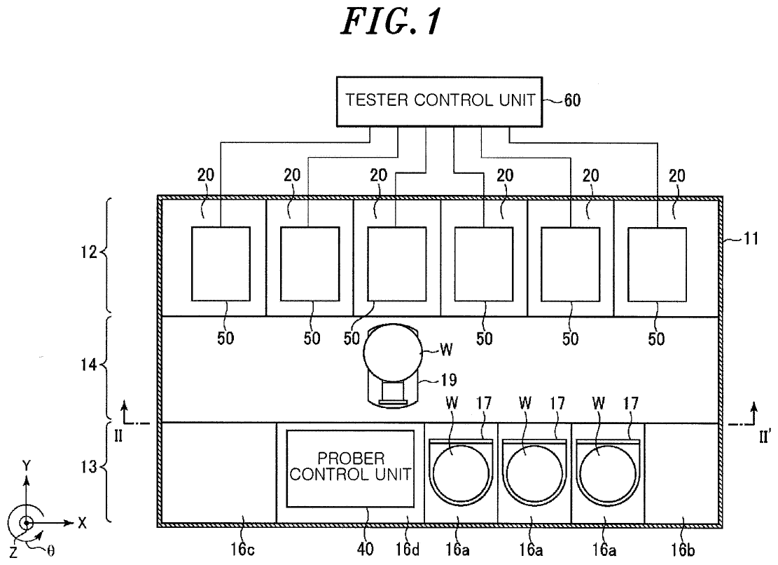

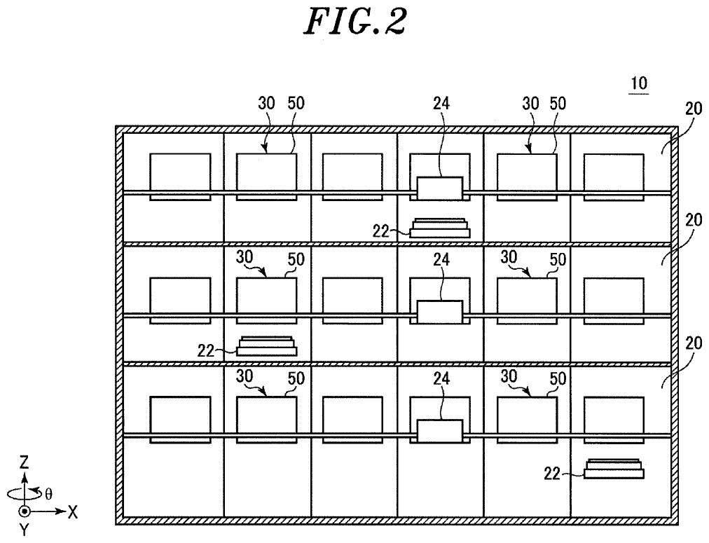

FIG. 1 is a horizontal cross-sectional view schematically showing the overall configuration of the testing system according to the embodiment of the present disclosure. FIG. 2 is a cross-sectional view taken along a line II-II′ of the testing system shown in FIG. 1. The testing system 10 of the present embodiment is configured to test electrical characteristics of a plurality of devices formed on a wafer that is an object to be tested.

The testing system of the present embodiment includes a plurality of testers and a prober. The prober includes a mechanism for transferring wafers to the plurality of testers, a wafer stage (chuck top) for attracting and holding a wafer corresponding to each tester, and an interface such as a probe card or the like. The interface is provided to establish an electric connection between device under tests (hereinafter referred to as “DUTs”) formed on the wafer and each tester.

Referring to FIG. 1, the testing system 10 includes a housing 11 having a testing area 12, a loading/unloading area 13, and a transfer area 14. In the testing area 12, the electrical characteristics of the DUTs formed on the wafer W are tested. In the loading/unloading area 13, the wafer W or the probe card is loaded into or unloaded from the testing area 12. The loading/unloading area 13 has a control system. The transfer area 14 is disposed between the testing area 12 and the loading/unloading area 13. Through the transfer area 14, the wafer W or the like is transferred between the testing area 12 and the loading/unloading area 13.

In the testing area 12, as shown in FIG. 2, six testing chambers (cells) 20 are arranged along the X direction in a row and rows of the testing chambers are arranged in three stages, respectively, along the Z direction (vertical direction). The testing chambers have testers 50 for testing DUTs formed on each wafer W. The testers 50 are controlled by a tester control unit 60.

Further, in each stage, a single aligner 22 is provided below the testers 50 and serves a wafer transfer table capable of moving along the arrangement direction (the X direction) of the testing chambers 20. In addition, a single upper camera 24 for position-alignment is disposed in each stage of the testing area 12 to be movable along the X direction closer to the transfer area 14 compared to the testers 50.

The loading/unloading area 13 is divided into a plurality of ports. Installed in the ports are a plurality of wafer loading/unloading ports 16a, a pre-alignment unit 16b, a probe card loader 16c, and a control port 16d. Each of the wafer loading/unloading ports 16a receives a FOUP 17 that is a container accommodating a predetermined number of wafers W. The pre-alignment unit 16b performs position-alignment of the wafer to be transferred. The probe card loader 16c stores the probe card that is loaded into or unloaded from the probe card loader 16c. In the control port 16d, a prober control unit 40 for controlling an operation of the prober of the testing system 10 is disposed.

In the transfer area 14, a transfer mechanism 19 having a plurality of transfer arms is disposed. A main body of the transfer mechanism 19 is movable in the Z direction and in the θ direction, and the transfer arms are movable in the forward-backward direction. Accordingly, the transfer mechanism 19 is configured to move the wafer W in the X direction, the Y direction, the Z direction, and the θ direction. The transfer mechanism 19 can access the testing chambers 20 of all stages. The transfer mechanism 19 transfers the wafer W from the wafer loading/unloading port 16a of the loading/unloading area 13 to the chuck top (wafer stage) in a testing unit 30. Further, the transfer mechanism 19 transfers the wafer W having devices whose electrical characteristics have been tested from the chuck top of the corresponding testing unit 30 to the wafer loading/unloading port 16a. At this time, the transfer of the wafer W to and from the chuck top is performed using the aligner 22 as will be described later. The aligner 22 and the transfer mechanism 19 constitute a wafer transfer unit.

The transfer mechanism 19 also transfers a probe card requiring maintenance from each testing chamber 20 to the probe card loader 16c and transfers a new probe card or a probe card that has been subjected to maintenance to each testing chamber 20.

In each testing chamber 20, the testing unit 30 having the tester 50 and other elements for testing are disposed.

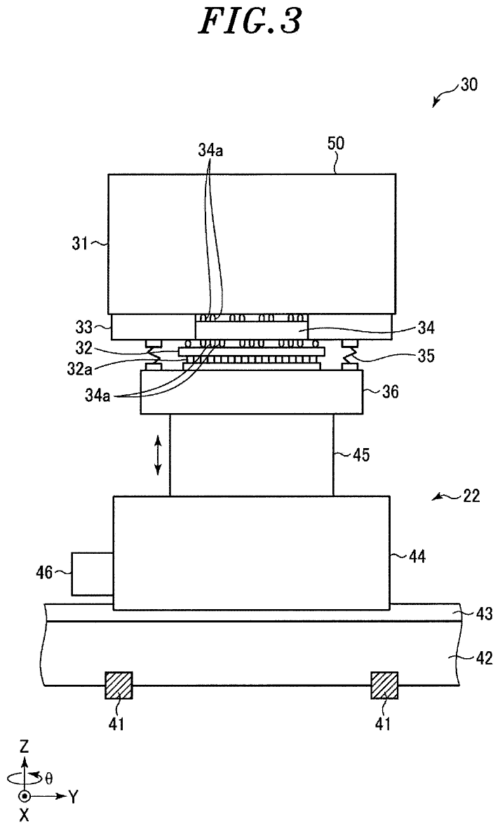

FIG. 3 shows a schematic configuration of the testing unit 30. The testing unit 30 includes, in addition to the tester 50, a probe card 32, a holding plate 33, a contact block 34, a bellows 35, and a chuck top (stage) 36. The probe card 32 has a plurality of probes 32a to be in contact with electrodes of devices formed on the wafer W. The holding plate 33 is disposed below the tester 50 to hold the probe card 32. The contact block 34 is configured to connect the tester 50 and the probe card 32. The bellows 35 is suspended from the holding plate 33 and surrounds the probe card 32. The chuck top (stage) 36 is configured to attract and hold the wafer W by vacuum attraction and control a temperature of the wafer W. A plurality of pogo pins 34a are disposed on an upper surface and a bottom surface of the contact block 34 to electrically connect the probe card 32 and the tester 50. Among these components, the probe card 32, the holding plate 33, and the contact block 34 constitute an interface for testing.

The bellows 35 is used for forming a sealed space including the probe card 32 and the wafer W in a state where the probes 32a of the probe card 32 are in contact with the wafer W on the chuck top 36. By evacuating the sealed space through a vacuum line, the chuck top 36 is coupled to the holding plate 33 by vacuum attraction force. Similarly, by evacuating the sealed space, the probe card 32 is also coupled to the holding plate 33 by vacuum attraction force.

The aligner 22 in each stage includes an X block 42, a Y block 44, and a Z block 45. The X block 42 moves in the X direction on a guide rail 41 disposed on a base plate of the stage where the aligner 22 is disposed. The Y block 44 moves in the Y direction on a guide rail 43 disposed on the X block 42 along the Y direction. The Z block 45 moves in the Z direction with respect to the Y block 44. The chuck top 36 is engaged with the Z block 45 while maintaining a predetermined positional relationship. A lower camera 46 for capturing an image of the bottom surface of the probe card 32 is disposed on a circumferential wall of the Y block 44.

The aligner 22 can move in the X direction to access to a position directly below each testing unit 30. The aligner 22 has the following four functions. First, the aligner 22 can support the chuck top 36 when the wafer W is transferred W from the transfer mechanism 19 to the chuck top 36 of each testing unit 30. Second, the aligner 22 can perform the position-alignment of the wafer W that is an object to be tested with respect to each testing unit 30. Third, the aligner 22 can bring the probe card 32 into contact with the wafer W on the chuck top 36. Fourth, the aligner 22 can receive the chuck top 36 when the chuck top is removed from the probe card 32. The aligner 22 further has a moving mechanism for moving the chuck top, on which the wafer is mounted, in the X, Y, and Z directions.

The wafer W is transferred to the chuck top 36 and brought into contact with the probe card 32 in the following manner. First, a wafer is transferred from the transfer mechanism 19 onto the chuck top 36. Next, the wafer W is position-aligned with respect to the probe card 32. Then, the chuck top 36 is raised by the aligner 22 to bring the wafer W into contact with the probes 32a of the probe card 32. Thereafter, the chuck top 36 is further raised, and the wafer W is brought into press-contact with the probes 32a. In this state, the space surrounded by the bellows 35 is evacuated so that the chuck top 36 is coupled to the holding plate 33 by the vacuum attraction force and the press-contact state between the wafer and the probes 32a is maintained. In that state, the testing of the electrical characteristics using the tester 50 is initiated. Thereafter, the Z block 45 of the aligner 22 retreats downward and the aligner 22 is moved to a different testing unit 30 in which the testing has been completed. Then, for the different testing unit 30, the above-described operations are performed in reverse order so that the chuck top 36 after the completion of the testing is lowered and the tested wafer W on the chuck top 36 is returned to the FOUP 17 by the transfer mechanism 19.

The tester 50 includes a power supply unit having a device power supply (DPS) and a parametric measurement unit (PMU), a pattern generator, a timing generator, a circuit unit having a circuit for performing power supply to DUTs on a wafer, waveform input (driver), waveform measurement (comparator), measurement and output of a voltage and a current, and the like.

In the testing system 10, components other than the testers 50 constitute the prober. The prober control unit controls the prober, and the tester control unit 60 controls the testers.

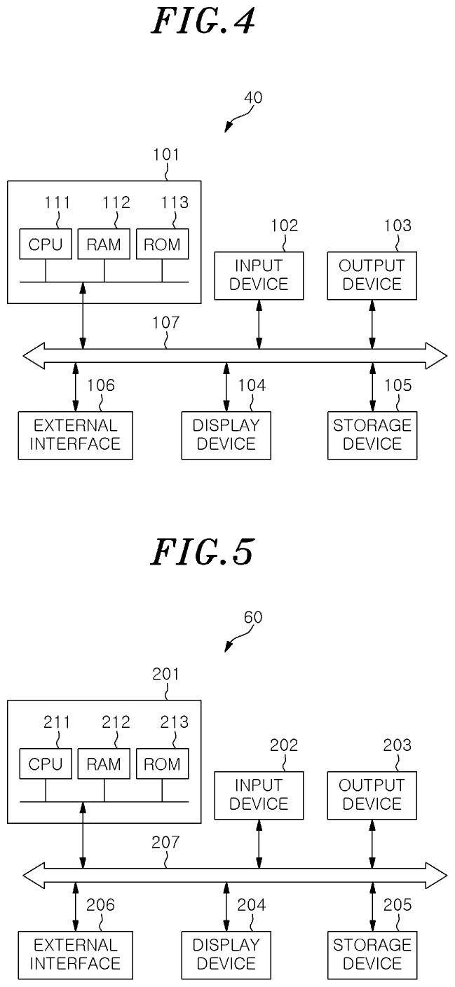

The prober control unit 40 includes a computer and is configured to control the respective components of the prober in the testing system 10 such as the aligner 22, the transfer mechanism 19, a vacuum mechanism for vacuum attraction, and the like. FIG. 4 shows an example of a hardware configuration of the prober control unit 40. The control unit 40 includes a main controller 101, an input device 102 such as a keyboard, a mouse, or the like, an output device 103 such as a printer or the like, a display device 104, a storage device 105, an external interface 106, and a bus 107 that connects the above components. The main controller 101 has a central processing unit (CPU) 111, a random access memory (RAM) 112, and a read only memory (ROM) 113. The storage device 105 writes and reads information on a computer-readable storage medium. The storage medium may be, e.g., a hard disk, an optical disk, or a semiconductor memory such as a flash memory. The storage medium stores a processing recipe for the prober, and the like.

In the prober control unit 40, the CPU 111 executes a program stored in the ROM 113 or the storage medium of the storage device 105 while using the RAM 112 as a working space, thereby controlling the operation of the vacuum mechanism and driving the transfer system of the testing system 10.

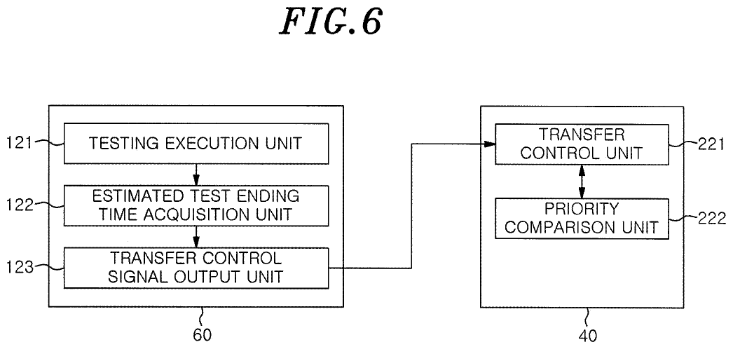

Similar to the prober control unit 40, the tester control unit 60 includes a computer and is configured to control the testers 50 of the testing system 10. FIG. 5 shows an example of a hardware configuration of the tester control unit 60. The tester control unit 60 includes a main controller 201, an input device 202 such as a keyboard, a mouse, or the like, an output device 203 such as a printer or the like, a display device 204, a storage device 205, an external interface 206, and a bus 207 that connects the above components. The main controller 201 has a CPU 211, a RAM 212, and a ROM 213. The storage device 205 writes and reads information on a computer-readable storage medium. The storage medium may be, e.g. a hard disk, an optical disk, or a semiconductor memory such as a flash memory. The storage medium stores a processing recipe for the prober and the like.

In the tester control unit 60, the CPU 211 controls each of the testers by executing a program stored in the ROM 213 or the storage medium of the storage device 205 while using the RAM 212 as a working space.

FIG. 6 is a functional block diagram for explaining the main control of the prober control unit 40 and the tester control unit 60 of the present embodiment. As shown in FIG. 6, the tester control unit 60 includes a testing execution unit 121 for executing a test, an estimated test ending time acquisition unit 122 for acquiring an estimated test ending time, and a transfer control signal output unit 123 for outputting a control signal (command) to the aligner 22 and the transfer mechanism 19. The prober control unit 40 includes a transfer control unit 221 for controlling the aligner 22 and the transfer mechanism 19, and a priority comparison unit 222. Although the prober control unit 40 and the tester control unit 60 have other control functions, only the main functions of the present embodiment are illustrated in FIG. 6.

The test (inspection) executed by the tester 50 includes a plurality of parts. After one part is completed, a command (signal) is transmitted from the tester 50 to the DUTs and a response of each DUT is checked. Thereafter, a next part is executed. However, the response time varies depending on the DUTs. If there are one or more DUTs that have not responded even after a predetermined period of time, the command transmission is repeated. Then, among the DUTs, DUTs that have failed to respond even after the command transmission is repeated a predetermined number of times are skipped and, then, the response is established only based on DUTs that have responded. The test proceeds to the next part after the response of the DUTs that have responded is established. Therefore, the response establishing time varies depending on wafers. Further, in a stress test that is one of the parts, the test time varies depending on the DUTs. In addition, the contents of the test, the contents of the parts, and the memory size vary depending on wafers W, so that the test time also varies. Accordingly, it is difficult to predict a test ending time before the test is started.

However, in the case when the test is executed by the testing execution unit 121 of the tester control unit 60 and the test has progressed to a predetermined stage, the test ending time can be predicted. Therefore, at the predetermined stage at which the test ending time can be predicted, an estimated test ending time is acquired by the estimated test ending time acquisition unit 122. The estimated test ending time acquisition unit 122 outputs the acquired estimated test ending time to the transfer control signal output unit 123. Then, the transfer control signal output unit 123 outputs a control signal (command) to the transfer control unit 221 of the prober control unit 40 such that a next wafer W can be prepared in the corresponding tester 50 before the estimated test ending time (so that the next wafer W can be loaded into the testing chamber 20). The transfer control unit 221 controls the transfer mechanism 19 and the aligner 22 constituting the transfer unit such that the wafer W can be transferred into the testing chamber 20 having the corresponding tester 50 before the estimated test ending time.

Since there are multiple testers 50, the DUTs on the respective wafers are tested simultaneously by the multiple testers 50, and control signals for the individual multiple testers 50 are outputted from the transfer control signal output unit 123 to the transfer control unit 221. Thus, if the transfer control unit 221 receives a control signal for one tester 50 and performs the transfer operation of the wafer W, and then the transfer control unit 221 receives a control signal (command) for another tester 50 before the transfer operation of the wafer W is completed, the priority comparison unit 222 compares priorities of the control signals. The priority comparison unit 222 causes the transfer mechanism 19 and the aligner 22 constituting the transfer unit to perform the transfer operation based on one of the control signals having a higher priority.

<Testing Method>

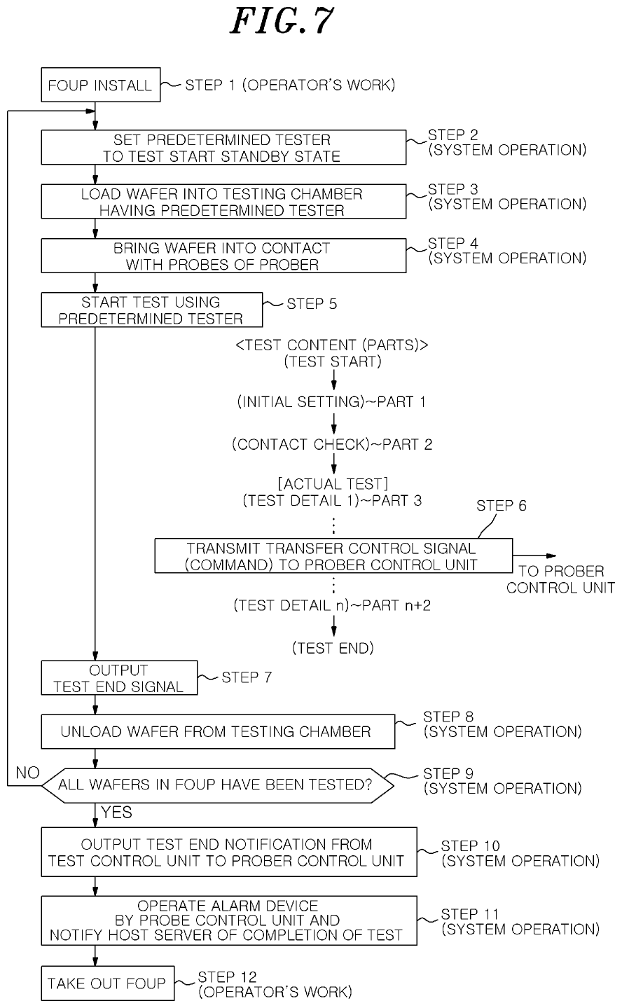

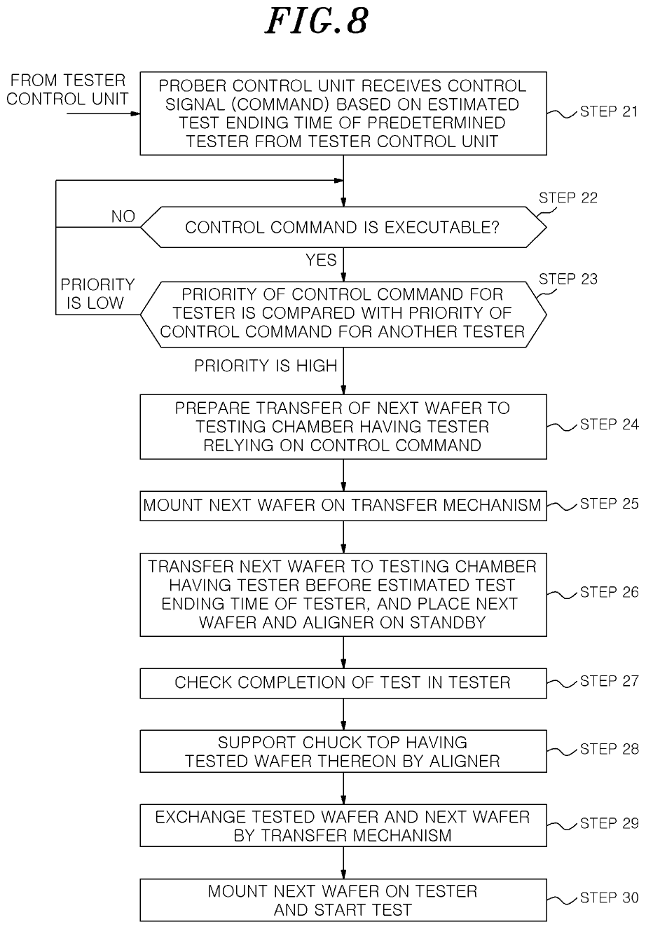

Next, a testing method in the testing system 10 configured as described above will be described. FIG. 7 is a flowchart showing a schematic flow on the tester 50 side in the testing method of the testing system 10. FIG. 8 is a flowchart showing a control flow on the prober control unit 40 side in the case of receiving a control signal from the tester control unit 60.

As shown in FIG. 7, on the tester side, an operator installs the FOUP(s) 17 to the wafer loading/unloading port(s) 16a (step 1). Then, a predetermined tester 50 is set to a test start standby state (step 2 (system operation)).

Next, the wafer W is loaded into the testing chamber having the predetermined tester 50 by the transfer mechanism 19 and the aligner 22 (step 3 (system operation)). In the case of loading the wafer, the aligner 22 is moved to the corresponding testing chamber 20 and the wafer W is transferred from the transfer mechanism 19 onto the chuck top 36 of the testing unit 30 in the testing chamber 20 in a state where the chuck top 36 is mounted on the aligner 22.

Next, the wafer W (the DUTs formed on the wafer W) is brought into contact with the probes 32a of the prober 32 (step 4 (system operation)). At this time, the position-alignment between the wafer W on the chuck top 36 and the prober 32 in the X-Y direction is performed by the aligner 22 and, then, the Z block 45 of the aligner 22 is raised to bring the DUTs of the wafer W into contact with the probes of the probe card 32. The position-alignment at this time is performed using the upper camera 24 and the lower camera 46. Then, a sealed space including the probe card 32 and the wafer W is formed by the bellows 35. By evacuating the sealed space through a vacuum line, the chuck top 36 is coupled to the holding plate 33 by the vacuum attraction force. Thereafter, the aligner 22 becomes free and can move to another testing chamber 20.

Next, the test using the tester 50 is started (step 5). At this time, the testing execution unit 121 of the tester control unit 60 executes the test content shown in FIG. 7. The test content includes multiple parts. For example, after the test is started, an initial setting (part 1), a contact check (part 2), and an actual test (test details 1 to n (parts 3 to n+2)) are performed.

When the test using the tester 50 has reached a predetermined stage at which the test ending time can be estimated, a transfer control signal (command) is transmitted to the prober control unit 40 (step 6). Specifically, when the test has reached the predetermined stage, the subsequent operations to be performed on any wafer W are the same. Therefore, the estimated test ending time acquisition unit 122 acquires an estimated test ending time at this stage. The transfer control signal output unit 123 outputs a control signal (command) to the transfer control unit 221 of the prober control unit 40 so that the aligner 22 and the transfer mechanism 19 on which the wafer W is mounted move to the testing chamber 20 having the corresponding tester 50 before the estimated test ending time.

When the test details 1 to n are completed, the test is ended and a test end signal is outputted (step 7). Next, the wafer W is unloaded from the testing chamber 20 (step 8 (system operation)). Then, the aligner 22 moves to the testing chamber 20 and performs the position-alignment in the X-Y direction. Next, the Z block 45 is raised so that the aligner 22 can support the chuck top 36. Thereafter, the wafer W is separated from the probe card 32 by releasing the vacuum in the space formed by the bellows 35 and, then, the Z block 45 is lowered. In this state, the transfer mechanism 19 receives the wafer W from the chuck top 36 on the aligner 22 and transfers the wafer W to the FOUP 17.

The above-described operations are performed on multiple wafers W using the multiple testers 50. When it is detected that all the wafers in the FOUP 17 have been tested (step 9 (system operation)), the tester control unit 60 outputs test end notification to the prober control unit 50 (step 10 (system operation). The probe control unit 40 that has received the test end notification causes an alarm device (not shown) to generate an alarm sound and Patlite (Registered Trademark) to flicker in order to notify a host server (customer server) of the completion of the test (step (system operation)). Next, an operator takes out the FOUP 17 (step 12).

Meanwhile, as shown in FIG. 8, the prober control unit 40 receives a control signal (command) based on an estimated test ending time of a predetermined tester 50 from the tester control unit 60 (step 21). Specifically, the transfer control unit 221 of the prober control unit 40 receives the control signal based on the estimated test ending time of the predetermined tester 50 from the transfer control signal output unit 123 of the tester control unit 60.

Next, it is determined whether or not the control command is executable (step 22). When the control command is executable, if a control signal (command) from another tester is being received, the priorities thereof are compared with each other (step 23). If the priority of the initial control command is higher, the next wafer W to be tested is prepared to be transferred to the testing chamber having the predetermined tester 50 that relies on the initial control command (step 24). Then, the next wafer W is mounted on the transfer mechanism 19 (step 25) and transferred by the transfer mechanism 19 to the testing chamber 20 having the predetermined tester 50 before the estimated test ending time of the corresponding tester 50. Thus, the next wafer W and the aligner 22 are placed to be on standby (step 26).

After the completion of the test in the corresponding tester 50 is checked (step 27), the chuck top 36 on which the tested wafer W is mounted is supported by the aligner 22 (step 28) and the tested wafer W and the next wafer W to be tested are exchanged by the transfer mechanism 19 (step 29). Thereafter, the next wafer W is mounted on the corresponding tester 50 and the test is started (step 30).

On the other hand, if the priority of the initial control command is lower, the control command from another tester is executed first. The priority is determined such that the wafer W can be more efficiently transferred based on the estimated test ending time and the moving time (moving distance) of the aligner 22 and the transfer mechanism 19 on which the wafer W is mounted (hereinafter, referred to as “transfer unit”). For example, this is the case when the moving time of the transfer unit for arriving at a first testing chamber 20 having a tester 50 relying on a control command that is initially received is longer than the moving time of the transfer unit for arriving at a second testing chamber 20 having a tester 50 relying on a control command that is received subsequent to the initial control command. That is to say, if the moving time of the transfer unit for arriving at a testing chamber 20 is shorter than the estimated test ending time of another tester 50, the transfer of the wafer W to the another tester 50 has a higher priority. Further, the priority of a wafer or a FOUP may be set such that the wafer or the FOUP to be tested first has a higher priority.

The number of control signals whose priorities are to be compared may be three or more. However, too many control signals whose priorities are to be compared can cause the controls to become too complicated. Therefore, it is preferable to limit the number of control signals whose priorities are to be compared to, e.g., two or three. It is also possible to transfer a next wafer to a corresponding tester 50 and have the next wafer on standby in the order of the received control signals without comparing priorities.

Conventionally, a tester and a prober are generally controlled by separate control systems. Particularly, in the testing system having multiple testing units disclosed in Patent Document 1, a signal is transmitted when a testing of a wafer in a tester of one testing unit is completed, and the aligner of the prober moves to the corresponding testing unit to take the wafer based on the signal. Therefore, it is not always possible to take the tested wafer at an optimum timing. Further, since the test ending time varies depending on the wafers, it is difficult to predict the test ending time. Accordingly, the standby time of each tester in the case of consecutively transferring and testing the wafers increases, and such a problem is not solved even by using the technique disclosed in Patent Document 2.

On the other hand, in the present embodiment, before the test in the predetermined tester 50 is completed, the tester control unit 60 acquires the estimated test ending time and transmits a control signal (command) based on the estimated test ending time to the prober control unit 40 as described above. Then, the prober control unit 40 controls the transfer mechanism 19 on which a next wafer W to be tested is mounted and the aligner 22 such that the next wafer can be ready to be loaded into the testing chamber 20 before the estimated test ending time. Therefore, it is possible to reduce a period of time between the end of the testing of the wafer W in each tester 50 and the start of the testing of the next wafer W in the corresponding tester 50 and to reduce the test lead time. Accordingly, the test efficiency of the entire testing system can be improved.

Further, when a plurality of control signals (commands) is received from the tester control unit 60, the prober control unit 40 can compare priorities of the control signals and transfer the wafer W to the tester 50 based on a control signal having a higher priority. By prioritizing the control signal that allows more efficient transfer of the wafer W, the test efficiency can be further improved. In addition, by setting the priority of a wafer or a FOUP such that the wafer or the FOUP with a higher priority is to be tested first, a specific type of wafer or a wafer contained in a specific FOUP can be tested first.

<Other Applications>

The presently disclosed embodiments are considered in all respects to be illustrative and not restrictive. The above-described embodiments can be embodied in various forms. Further, the above-described embodiments may be omitted, replaced, or changed in various forms without departing from the scope of the appended claims and the gist thereof.

For example, the above-described embodiments have described the case where the present disclosure is applied to a testing system having a plurality of testers. However, the present disclosure is not limited thereto and may be applied to a testing system having one tester.

Further, in the above-described embodiments, the control command from the tester control unit to the prober control unit is to prepare a next wafer for the tester. However, the control command is not limited thereto and may be another control command. For example, when a sign of a poor measurement accuracy due to needle tip contamination (probe tip contamination) is detected during a test, a control command such as needle polishing (probe polishing), needle tip check (probe tip check), or the like is transmitted from the tester control unit to the prober control unit. Accordingly, the control demand can be checked at an optimal timing.

### DESCRIPTION OF REFERENCE NUMERALS

10: testing system
17: FOUP
19: transfer mechanism (transfer unit)
20: testing chamber
22: aligner (transfer unit)
30: testing unit
36: chuck top
40: prober control unit
50: tester
60: tester control unit
121: testing execution unit
122: estimated test ending time acquisition unit
123: transfer control signal output unit
221: transfer control unit
222: priority comparison unit
W: wafer (object to be tested)

1. A testing system comprising:
a prober including a stage configured to hold a target object on which a plurality of devices to be tested is formed in a testing chamber, a loading/unloading port on which a container accommodating a plurality of target objects is mounted, a transfer unit configured to transfer each of the target objects from the container to the stage, and a probe card having a plurality of probes to be in contact with the devices to be tested formed on each of the target objects;
at least one tester configured to apply electrical signals to the devices formed on each of the target objects through the probe card in the testing chamber and test electrical characteristics of the devices;
a prober control unit configured to control the prober; and
a tester control unit configured to control the tester,
wherein the tester control unit
causes the tester to execute a test that includes a plurality of parts on the devices,
acquires an estimated test ending time when the test has reached a predetermined stage, and
transmits a control signal to the prober control unit so that a next target object is to be loaded into the testing chamber having the tester before the estimated test ending time.

2. The testing system of claim 1, wherein the prober control unit controls the transfer unit based on the control signal from the tester.

3. The testing system of claim 1, wherein the at least one tester includes two or more testers, and the prober includes two or more testing chambers, two or more stages, and two or more probe cards to correspond to the two or more testers, each of the testing chambers, the stages and the probe cards corresponding to the testing chamber, the stage and the probe card of claim 1, and
the transfer unit transfers each of the target objects between the container and the testing chambers.

4. The testing system of claim 3, wherein when the prober control unit receives the control signals from the two or more testers, the prober control unit compares priorities of the control signals and controls the transfer unit based on one of the control signals having a higher priority.

5. The testing system of claim 4, wherein the prober control unit determines the priorities based on the estimated test ending time and a moving time of the transfer unit to more efficiently transfer the target objects.

6. The testing system of claim 4, wherein the prober control unit presets the number of the control signals whose priorities are to be compared.

7. The testing system of claim 1, wherein the estimated test ending time is acquired at the predetermined stage of the test at which a test ending time of the test is predictable.

8. A testing method comprising:
preparing a testing system including a prober having a stage configured to hold a target object on which a plurality of devices to be tested is formed in a testing chamber, a loading/unloading port on which a container accommodating a plurality of target objects is mounted, a transfer unit configured to transfer each of the target objects from the container to the stage, and a probe card having a plurality of probes to be in contact with the devices to be tested formed on each of the target objects; at least one tester configured to apply electrical signals to the devices formed on each of the target objects through the probe card in the testing chamber to test electrical characteristics of the devices; a prober control unit configured to control the prober; and a tester control unit configured to control the tester;
causing the tester to execute a test that includes a plurality of parts on the devices; and
causing the tester control unit to acquire an estimated test ending time when the test has reached a predetermined stage and transmit a control signal to the prober control unit so that a next target object is to be loaded into the testing chamber having the tester before the estimated test ending time.

9. The testing method of claim 8, wherein the prober control unit controls the transfer unit based on the control signal from the tester.

10. The testing method of claim 8, wherein the at least one tester in the testing system includes two or more testers and the prober includes two or more testing chambers, two or more stages, and two or more probe cards to correspond to the two or more testers, each of the testing chambers, the stages and the probe cards corresponding to the testing chamber, the stage and the probe card of claim 8, and
the transfer unit transfers each of the target objects between the container and the testing chambers.

11. The testing method of claim 10, wherein when the prober control unit receives the control signals from the two or more testers, the prober control unit compares priorities of the control signals and controls the transfer unit based on one of the control signals having a higher priority.

12. The testing method of claim 11, wherein the prober control unit determines the priorities based on the estimated test ending time and a moving time of the transfer unit to more efficiently transfer the target objects.

13. The testing method of to claim 11, wherein the prober control unit presets the number of the control signals whose priorities are to be compared.

14. The testing method of claim 8, wherein the estimated test ending time is acquired at the predetermined stage of the test at which a test ending time of the test is predictable.
